(19) United States
(12) Patent Application Publication
(10) Pub. No.: US 2002/0195599 A1
(43) Pub. Date: Dec. 26, 2002

(54) Low-defect semiconductor structure, device including the structure and method for fabricating structure and device

(75) Inventors: Zhiyi Yu, Gilbert, AZ (US); Ravindranath Droopad, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/884,150

(22) Filed: Jun. 20, 2001

(51) Int. Cl. H01L 29/06; H01L 31/0328; H01L 31/0336; H01L 31/072; H01L 31/109; H01L 21/31; H01L 21/469

(52) U.S. Cl. 257/18; 438/767

(57) ABSTRACT

High quality epitaxial layers of monocrystalline materials can be grown overlying monocrystalline substrates such as large silicon wafers (22) by forming a compliant substrate for growing the monocrystalline layers. One way to achieve the formation of a compliant substrate includes first growing an accommodating buffer layer (24) on a silicon wafer (22). The accommodating buffer layer (24) is a layer of monocrystalline oxide spaced apart from the silicon wafer (22) by an amorphous interface layer (28) of silicon oxide. The amorphous interface layer (28) dissipates strain and permits the growth of a high quality monocrystalline oxide accommodating buffer layer.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer overlying a compliant substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monocrystalline thin films on a foreign substrate such as silicon (Si). To achieve optimal characteristics of the various monocrystalline layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of the material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having a grown monocrystalline film. This monocrystalline material layer may include a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, 3, and 4 illustrate schematically, in cross section, device structures in accordance with various embodiments of the invention;

FIG. 5 illustrates graphically the relationship between maximum attainable film thickness and lattice mismatch between a host crystal and a grown crystalline overlayer;

FIG. 6 illustrates a high resolution Transmission Electron Micrograph of a structure including a monocrystalline accommodating buffer layer;

FIG. 7 illustrates an x-ray diffraction spectrum of a structure including a monocrystalline accommodating buffer layer;

FIG. 8 illustrates a high resolution Transmission Electron Micrograph of a structure including an amorphous oxide layer;

FIG. 9 illustrates an x-ray diffraction spectrum of a structure including an amorphous oxide layer;

FIGS. 10-13 illustrate schematically, in cross-section, the formation of a device structure in accordance with another embodiment of the invention;

FIGS. 14-15 illustrate schematically, in cross-section, the formation of a device structure in accordance with still another embodiment of the invention;

FIGS. 16-20 illustrate schematically, in cross-section, the formation of yet another embodiment of a device structure in accordance with the invention, having an electrical component formed using a grown monocrystalline film; and

FIGS. 21-27 illustrate schematically, in cross-section, the formation of yet another embodiment of a device structure in accordance with the invention, including a light-emitting device.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a (100) oriented monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry.

In another embodiment of the invention, substrate 22 may comprise a (100) Group IV material that has been off-cut towards a (011) direction. The growth of materials on a miscut Si (100) substrate is known in the art. For example, U.S. Pat. No. 6,039,803, issued to Fitzgerald et al. on Mar. 21, 2000, which patent is herein incorporated by reference, is directed to growth of silicon-germanium and germanium layers on miscut Si (100) substrates. Substrate 22 may be off-cut in the range of from about 2 degrees to about 6 degrees towards the (011) direction. A miscut Group IV substrate reduces threading dislocations and results in improved quality of subsequently grown layer 26.

Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the accommodating buffer layer by the oxidation of substrate 22 during and/or after the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a unit cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements and typically have a perovskite crystalline structure. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), mixed II-VI compounds, Group IV and VI elements (IV-VI semiconductor compounds), mixed IV-VI compounds, Group IV semiconductors, and mixed Group IV compounds. Examples include gallium arsenide (GaAs), gallium indium arsenide (GaInAs), gallium aluminum arsenide (GaAlAs), gallium arsenic phosphide (GaAsP), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), SiGe, SiGeC and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging form about 1 to about 10 monolayers.

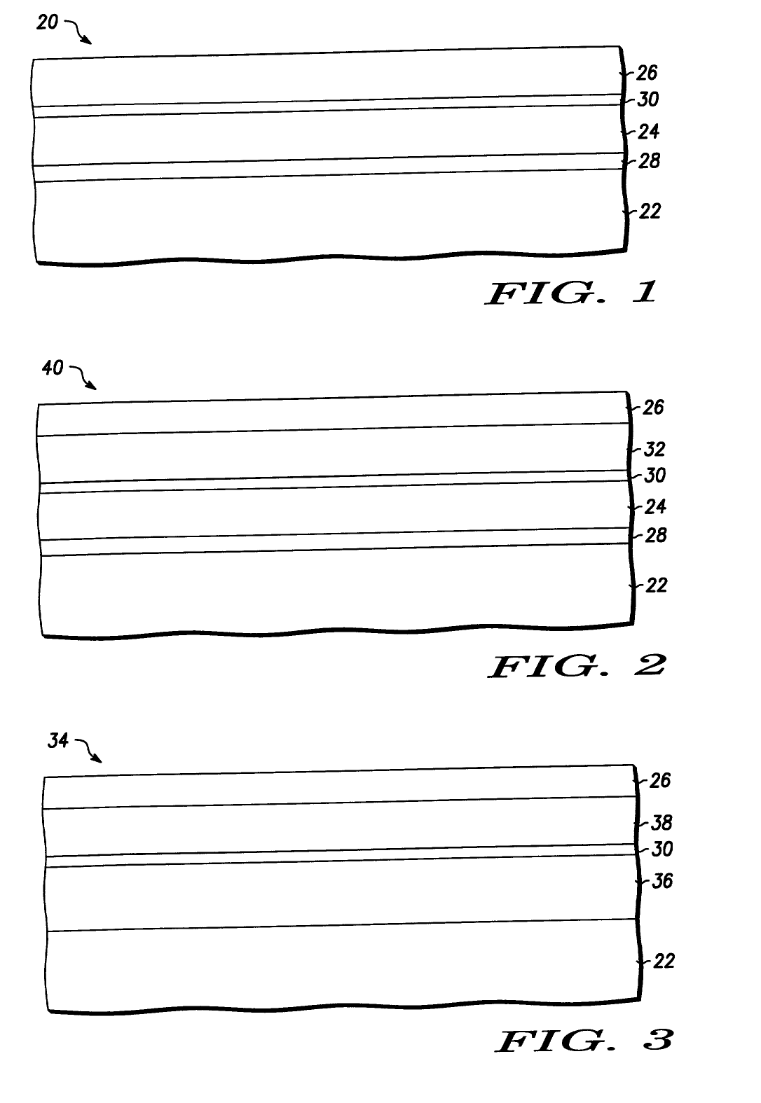

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

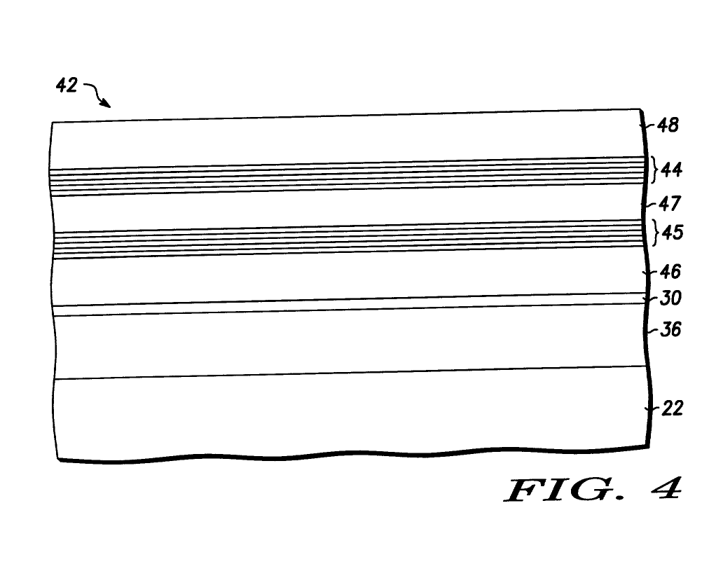

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal (e.g., conventional or rapid thermal anneal) process to convert the monocrystalline accommodating buffer layer to an amorphous layer and to improve the crystalline quality of the monocrystalline layer 38. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

FIG. 4 illustrates yet another structure 42 in accordance with the present invention. Structure 42 is similar to structure 34, except that structure 42 includes strained-layer superlattice portions 44 and 45 interposed between monocrystalline material portions 46 and 48. Strained-layer superlattice portions 44 and 45 serve to block or prevent migration of crystalline defects (e.g., threading dislocation) from migrating to subsequently formed layers. For example, strained-layer superlattice portion 44 is designed to reduce propagation of defects from monocrystalline material layer 46 to monocrystalline layer 47. Similarly, strained-layer superlattice portion 45 is configured to mitigate propagation of defects from monocrystalline material layer 47 to monocrystalline material layer 48. Although structure 42 is illustrated with two strained-layer superlattice portions, a structure in accordance with the present invention may include one or any other desired number of strained-layer superlattice portions. Further, although illustrated as formed over amorphous layer 36, a structure including strained-layer superlattice structures may be suitably formed overlying a monocrystalline accommodating buffer layer, such as layer 24, illustrated in FIGS. 1-3. As explained in more detail below, each strained-layer superlattice portions may include one or more layers of monocrystalline material, having a lattice constant that is larger than the lattice constant of the underlying film, which is epitaxially formed over a monocrystalline material layer. Strained-layer superlattice portions formed in this manner are strained in a compressive manner and tend to block or deflect threading dislocation defects originating in underlying layers.

The following non-limiting, illustrative examples illustrate various combinations of materials useful in structures 20, 40, 34, and 42 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction or misoriented about 2 degrees to about 6 degrees off (100) towards (011). The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) and/or aluminum gallium arsenide (AlGaAs) having a total thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide and/or aluminum gallium arsenide on the monocrystalline oxide, a template layer is formed by capping the oxide layer. The template layer is preferably 1-10 monolayers of Ti—As, Ti—O—As, Sr—O—As, Sr—Ga—O, Al—O—As, or Sr—Al—O. By way of a preferred example, 1-2 monolayers of Ti—O, Ti, Sr—O, or Sr have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. Additional buffer layer 32, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

### EXAMPLE 7

This example provides exemplary materials suitable for forming structure 42, illustrated in FIG. 4. Substrate 22 and amorphous layer 36 may include the same materials described above in connection with structure 34. Monocrystalline material portions 46-48 may include any of the material used to form monocrystalline material layer 26 as described above in connection with FIGS. 1-3. For example, portions 46, 47 may include a layer of GaAs, having a thickness of about 0.2 μm to about 5 μm, and preferably about 0.2 μm to about 0.5 μm, and layer 48 may include GaAs, having a thickness of about 0.2 μMm to about 5 μm, and preferably about 0.5 μm to about 2 μm.

Strained-layer superlattice portions 44, 45 generally include a material that, when formed overlying a monocrystalline layer, forms a monocrystalline film under compressive stress, which is closely lattice matched to the underlying and the overlying layer of monocrystalline material. In accordance with one aspect of this embodiment, a strained-layer superlattice portion includes a single layer of InGaAs (e.g., InₓGa₁₋ₓAs, where x ranges from 0.09 to 0.25) or GaAsP, having a thickness of about 0.1 μm to about 0.3 μm. In accordance with another aspect of this embodiment, strained-layer superlattice portions 44, 45 include multiple, alternating layers of material. For example, portions 44, 45 may include about 5 to about 10 periods of alternating InGaAs and GaAs layers, about 5 to about 10 periods of alternating GaAsP and GaAs layers, or the like, wherein each layer is about 1 to about 3 nm, and preferably about 2.5 nm.

Referring again to FIGS. 1-4, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

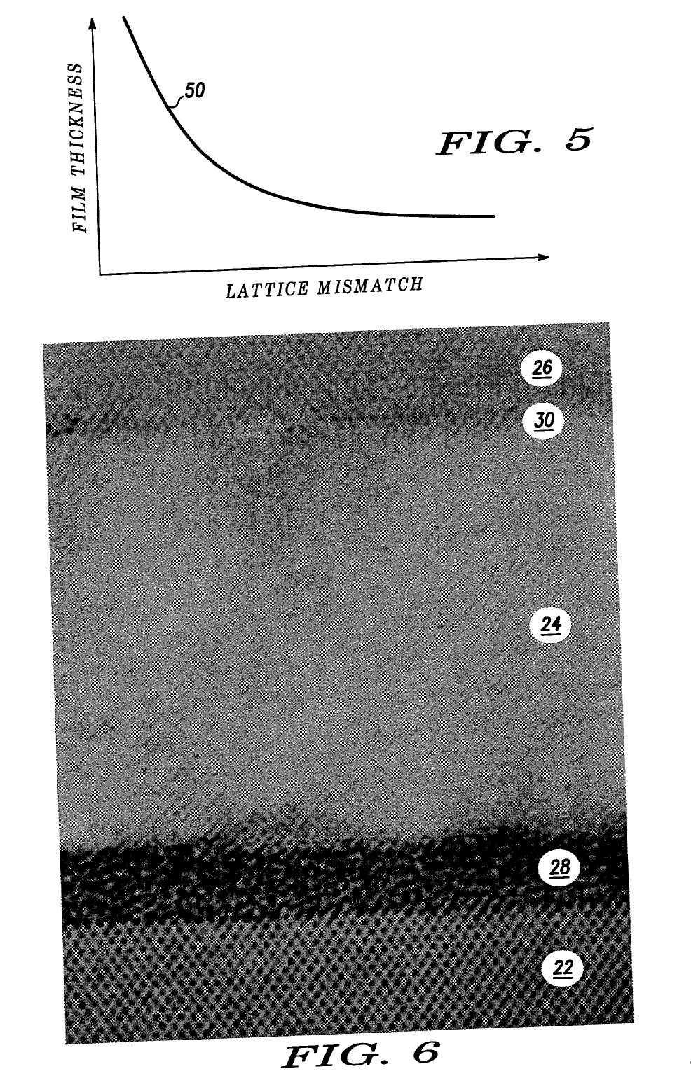

FIG. 5 illustrates graphically the relationship of the achievable thickness (“critical thickness”) of a grown crystal layer of high crystalline quality as a function of the mismatch between the lattice constants of the host crystal and the grown crystal. Curve 50 illustrates the boundary of high crystalline quality material. The area to the right of curve 50 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Layers 26 and 46 are layers of epitaxially grown monocrystalline material and that crystalline material is also characterized by a crystal lattice constant and a crystal orientation. In accordance with one embodiment of the invention, the lattice constant of layer 26 or 46 differs from the lattice constant of substrate 22. To achieve high crystalline quality in the epitaxially grown monocrystalline layer, the accommodating buffer layer must be of high crystalline quality. In addition, in order to achieve high crystalline quality in layer 26 or 46, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-4. The process starts by providing a monocrystalline semiconductor substrate comprising silicon or germanium. In accordance with a preferred embodiment of the invention, the semiconductor substrate is a silicon wafer having a (100) orientation. The substrate is preferably oriented off axis by about 2° to about 6° and preferably about 4°, preferably towards (011). At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A high quality thin silicon oxide may also be intentionally grown thermally (e.g., by conventional or rapid thermal oxidation) or chemically (e.g., by RCA method) on the semiconductor substrate, and such a grown oxide is preferred for the process in accordance with the invention. In order to epitaxially grow a monocrystalline oxide layer overlying the monocrystalline substrate, the amorphous silicon oxide layer must first be removed to expose the crystalline surface structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is kept at a temperature in the range of 200-800° C. during strontium deposition and is then heated to a temperature of about 730° C. to about 800° C. to cause the strontium to react with the amorphous silicon oxide layer. The strontium serves to reduce the silicon oxide to leave a silicon oxide-free surface. The resultant surface preferably exhibit an ordered 2×1 structure. If an ordered 2×1 structure has not been achieved at this stage of the process, the structure may be exposed to additional strontium until an ordered 2×1 structure is obtained. The ordered structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 730° C. to about 800° C. At this temperature a solid state reaction takes place between the strontium oxide and the native silicon oxide causing the reduction of the native silicon oxide and leaving an ordered 2×1 structure. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.2-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) single crystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen, 1-2 monolayers of strontium, or with 1-2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

After a suitable template is formed, a layer of monocrystalline material (e.g., layer 26 or 46) is formed overlying the monocrystalline accommodating buffer layer. The process for forming the monocrystalline material layer is preferably configured to facilitate two-dimensional or layer-by-layer growth of the monocrystalline material layer.

In accordance with one embodiment of the invention, a portion of the monocrystalline material is deposited at a relatively slow rate, in an effort to facilitate two-dimensional nucleation and to reduce formation of any crystalline defects. For example, a portion of layer 26 (or layer 46), which includes GaAs may be formed by co-depositing Ga and As with a growth rate of about 0.1-0.3 μm/hour and preferably about 0.2 μm/hour at a temperature about 300° C. to about 500° C., preferably about 350° C. to about 450° C., for about 5 minutes to about 10 minutes. This process is preferably carried out in a layer-by-layer method, such that, for example, a layer of arsenic is initially deposited, followed by a layer of gallium, and so on. After the initial portion of layer 26 is formed (e.g. to a thickness of about 10-100 nm or a critical thickness as described above in connection with FIG. 5, the structure may optionally be exposed to an anneal process to allow migration of atoms on the surface of the structure and to further improve the crystalline quality of the initial structure. In this case, the structure is annealed, preferably in-situ, at a temperature of about 550° C. to about 800° C. for about 1 minute to about 20 minutes, and preferably about 5 minutes to about 10 minutes. If layer 26 includes GaAs, the anneal process is preferably performed in an arsenic overpressure environment to prevent or reduce degradation of the portion of layer 26 during the anneal process.

After the initial portion of layer 26 is formed and optionally exposed to an anneal process, the remaining portion of layer 26 is formed over the initial portion of layer 26. The deposition of the second portion is preferably performed at a higher deposition rate than the deposition rate of the initial portion of layer 26. In accordance with one aspect of this exemplary embodiment, the second portion is grown at a rate of about 0.4 μm/hour to about 1 μm/hour and preferably about 0.5 μm/hour at a temperature about 300° C. to about 700° C. for about 100 minutes to about 300 minutes, to an application-specific-desired thickness—e.g., about 0.5 μm to about 2 μm. After the second portion is grown, the structure may again be exposed to an anneal process, again preferably in-situ in the proper environment. When layer 26 comprises GaAs, the anneal process (after the second portion formation) is preferably carried out at a temperature of about 550° C. to about 800° C. and preferably about 550° C. to about 580° C. for a period of about 1 to about 20 minutes and preferably about 15 minutes. Although layer 26 (or 46) formation is described above as includes a two-stage deposition process, the formation of the layer may include additional “slow” or “fast” deposition steps, with optional anneal steps, as described above.

Referring now to FIG. 4, after layer 46 is formed, portions 44, 45 and additional monocrystalline material layers 47, 48 may be formed using epitaxial growth techniques. The additional film deposition steps may be performed in the same or different epitaxial film deposition apparatus.

An anneal process for forming layer 36 (e.g., from a monocrystalline accommodating buffer layer and an amorphous interface layer) may be performed at any time after at least a portion of layer 46 is formed. In accordance with one aspect of this embodiment, layer 36 is formed by exposing substrate 22, the accommodating buffer layer, and the amorphous oxide layer to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 46 may be required to prevent degradation of layer 46 during the anneal process, as discussed above.

FIG. 6 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

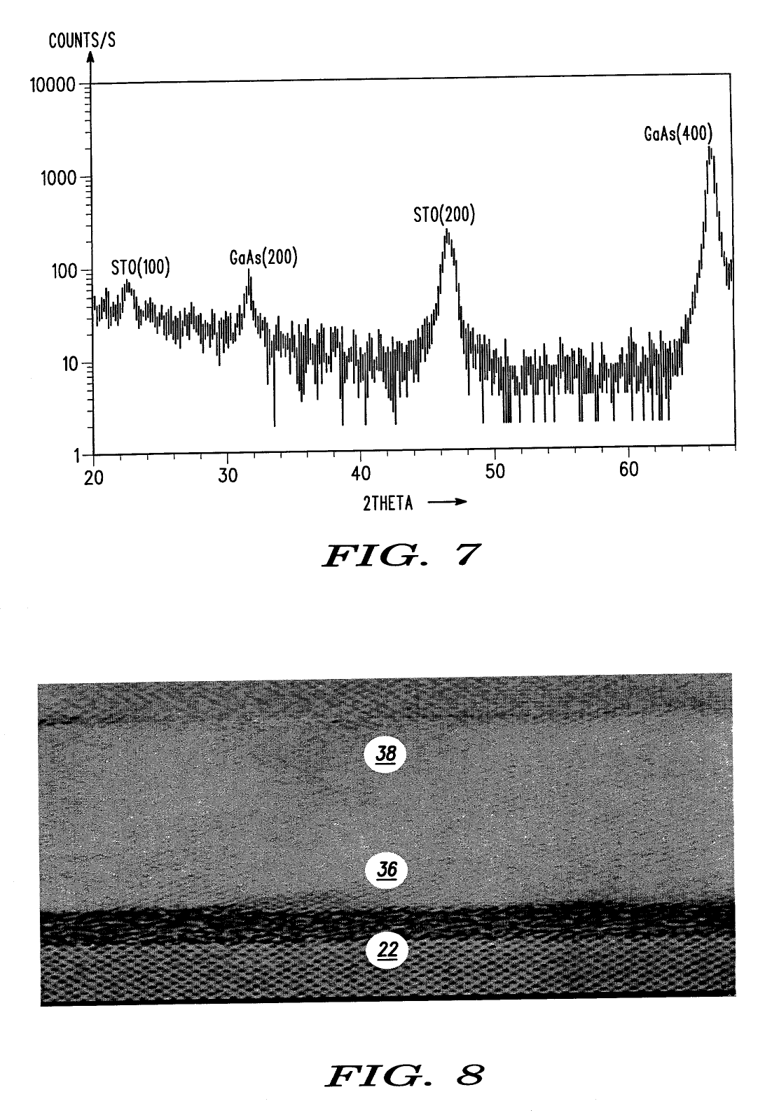

FIG. 7 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. Additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, as described above in connection with structure 42.

As noted above, layer 38 of structure 34 may include any materials suitable for either of layers 32 or 26. Accordingly, any deposition or growth methods described in connection with either layer 32 or 26, may be employed to deposit layer 38.

FIG. 8 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

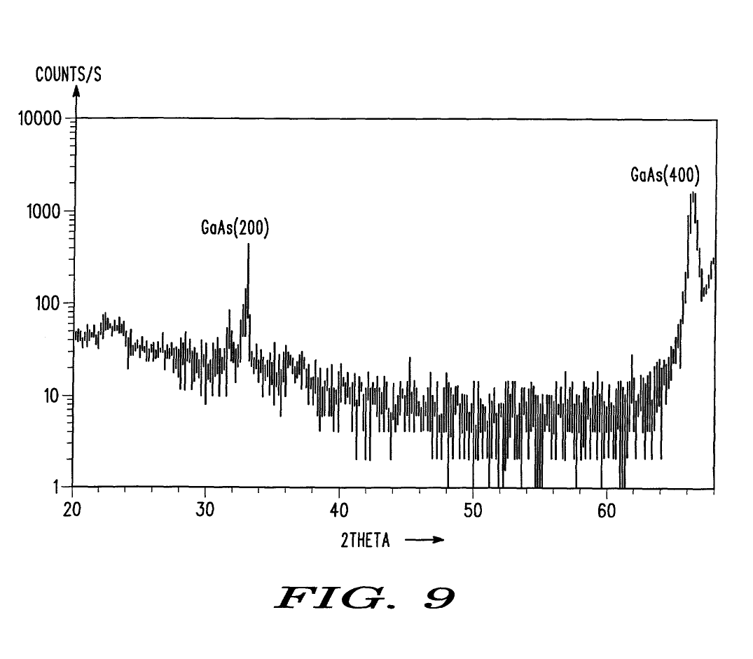

FIG. 9 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), migration enhanced epitaxy (MEE) or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V, II-VI, IV-VI and monocrystalline compound semiconductors, Group IV semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

Turning now to FIGS. 10-13, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 10. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-4.

Next, a silicon layer 81 is deposited over monocrystalline oxide layer 74 via MBE, CVD, MOCVD, MEE, ALE, PVD, CSD, PLD, or the like as illustrated in FIG. 11 with a thickness of a few hundred Angstroms but preferably with a thickness of about 50 Angstroms. Monocrystalline oxide layer 74 preferably has a thickness of about 20 to 100 Angstroms.

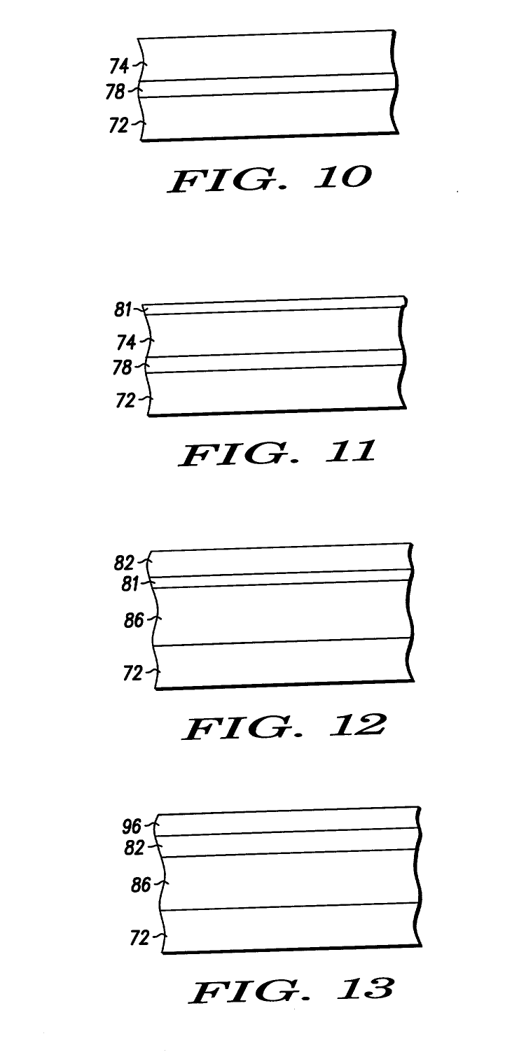

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 12. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an interface single crystal oxide layer that is amorphosized to form a silicate layer which adsorbs the strain between the layers. Moreover, unlike past use of a SiC substrate, this embodiment of the invention is not limited by wafer size which is usually less than 2 inches in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

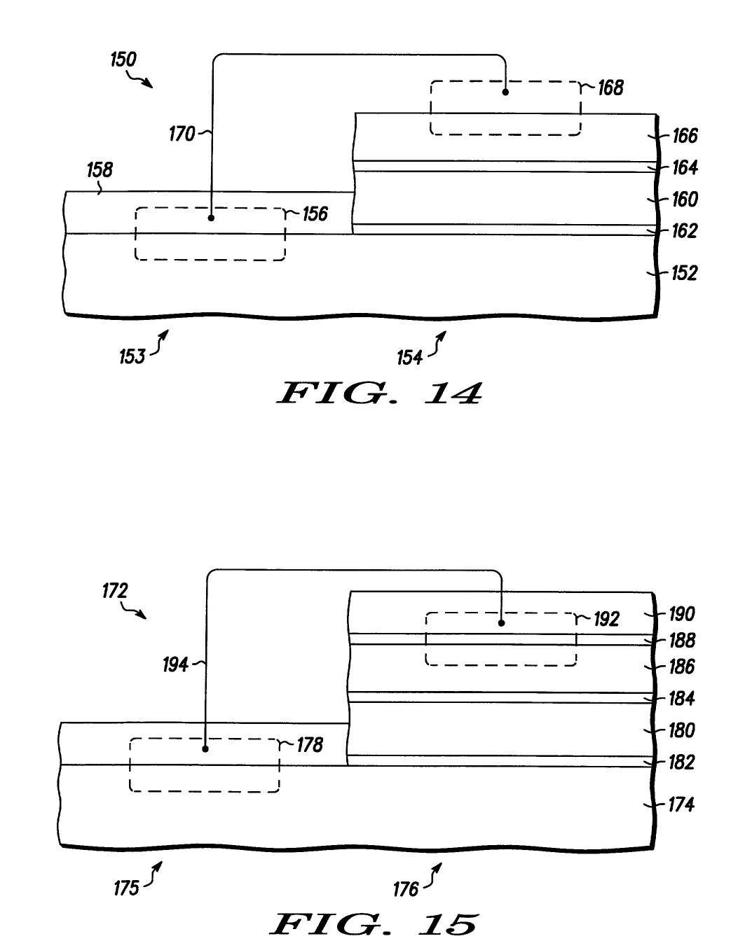

FIG. 14 illustrates schematically, in cross section, a device structure 150 in accordance with a further embodiment. Device structure 150 includes a monocrystalline semiconductor substrate 152, preferably a monocrystalline silicon wafer. Monocrystalline semiconductor substrate 152 includes two regions, 153 and 154. An electrical semiconductor component generally indicated by the dashed line 156 is formed, at least partially, in region 153. Electrical component 156 can be a resistor, a capacitor, an active semiconductor component such as a diode or a transistor or an integrated circuit such as a CMOS integrated circuit. For example, electrical semiconductor component 156 can be a CMOS integrated circuit configured to perform digital signal processing or another function for which silicon integrated circuits are well suited. The electrical semiconductor component in region 153 can be formed by conventional semiconductor processing as well known and widely practiced in the semiconductor industry. A layer of insulating material 158 such as a layer of silicon dioxide or the like may overlie electrical semiconductor component 156.

Insulating material 158 and any other layers that may have been formed or deposited during the processing of semiconductor component 156 in region 153 are removed from the surface of region 154 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 154 and is reacted with the oxidized surface to form a first template layer (not sown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 154 to form an amorphous layer of silicon oxide on second region 154 and at the interface between silicon substrate 152 and the monocrystalline oxide. Layers 160 and 162 may be subject to an annealing process as described above in connection with FIG. 3 to form a single amorphous accommodating layer.

In accordance with an embodiment, the step of depositing the monocrystalline oxide layer is terminated by depositing a second template layer 160, which can be 1-10 monolayers of titanium, barium, barium and oxygen, strontium and oxygen, strontium, titanium, or titanium and oxygen. A layer 166 of a monocrystalline compound semiconductor material is then deposited overlying second template layer 164 by a process of molecular beam epitaxy. The deposition of layer 166 is initiated by, for example, depositing a layer of arsenic onto template 164. This initial step is followed by depositing gallium and arsenic to form monocrystalline gallium arsenide 166. Next, a strained-layer superlattice structure may be formed, as discussed above in connection with FIG. 4, followed by the formation of an additional layer of GaAs. Additional strained-layer superlattice and monocrystalline material layers may be formed above the GaAs layer to mitigate migration of crystalline defects.

In accordance with a further embodiment, a semiconductor component, generally indicated by a dashed line 168 is formed in compound semiconductor layer 166. Semiconductor component 168 can be formed by processing steps conventionally used in the fabrication of gallium arsenide or other III-V compound semiconductor material devices. Semiconductor component 168 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 170 can be formed to electrically couple device 168 and device 156, thus implementing an integrated device that includes at least one component formed in silicon substrate 152 and one device formed in monocrystalline compound semiconductor material layer 166. Although illustrative structure 150 has been described as a structure formed on a silicon substrate 152 and having a barium (or strontium) titanate layer 160 and a gallium arsenide layer 166, similar devices can be fabricated using other substrates, monocrystalline oxide layers and other compound semiconductor layers as described elsewhere in this disclosure.

FIG. 15 illustrates a semiconductor structure 172 in accordance with a further embodiment. Structure 172 includes a monocrystalline semiconductor substrate 174 such as a monocrystalline silicon wafer that includes a region 175 and a region 176. An electrical component schematically illustrated by the dashed line 178 is formed in region 175 using conventional silicon device processing techniques commonly used in the semiconductor industry. Using process steps similar to those described above, a monocrystalline oxide layer 180 and an intermediate amorphous silicon oxide layer 182 are formed overlying region 176 of substrate 174. A template layer 184 and subsequently a monocrystalline semiconductor layer 186 are formed overlying monocrystalline oxide layer 180. In accordance with a further embodiment, an additional monocrystalline oxide layer 188 is formed overlying layer 186 by process steps similar to those used to form layer 180, and an additional monocrystalline semiconductor layer 190 is formed overlying monocrystalline oxide layer 188 by process steps similar to those used to form layer 186. In accordance with one embodiment, at least one of layers 186 and 190 are formed from a compound semiconductor material. Layers 180 and 182 may be subject to an annealing process as described above in connection with FIG. 3 to form a single amorphous accommodating layer.

A semiconductor component generally indicated by a dashed line 192 is formed at least partially in monocrystalline semiconductor layer 186. In accordance with one embodiment, semiconductor component 192 may include a field effect transistor having a gate dielectric formed, in part, by monocrystalline oxide layer 188. In addition, monocrystalline semiconductor layer 190 can be used to implement the gate electrode of that field effect transistor. In accordance with one embodiment, monocrystalline semiconductor layer 186 is formed from a group III-V compound and semiconductor component 192 is a radio frequency amplifier that takes advantage of the high mobility characteristic of group III-V component materials. In accordance with yet a further embodiment, an electrical interconnection schematically illustrated by the line 194 electrically interconnects component 178 and component 192. Structure 172 thus integrates components that take advantage of the unique properties of the two monocrystalline semiconductor materials.

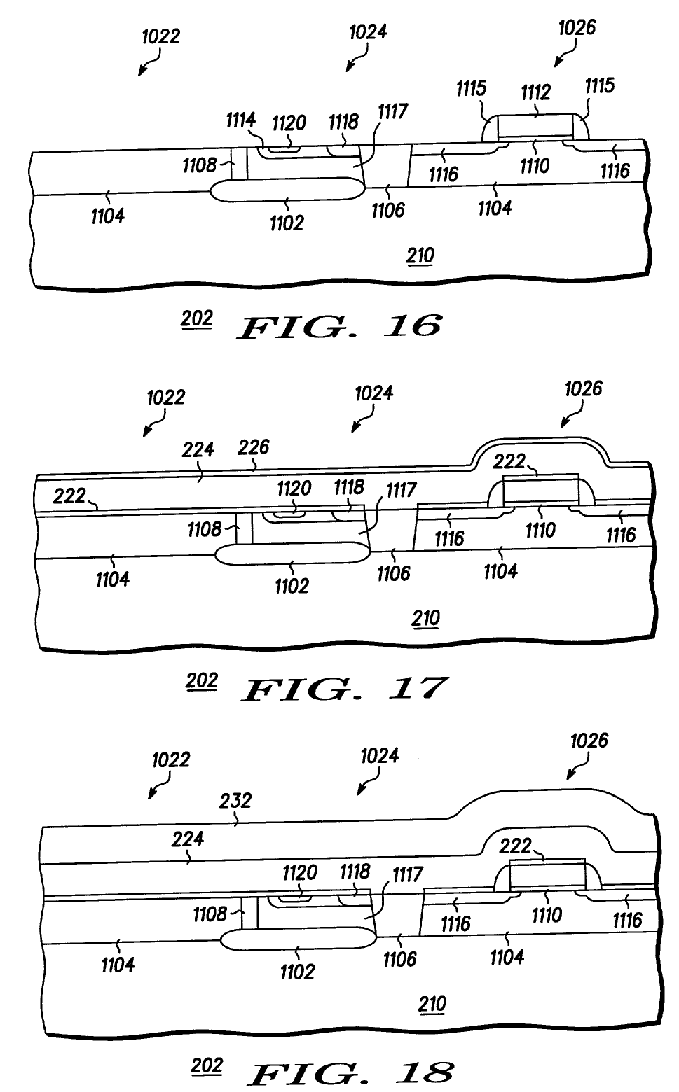

Attention is now directed to a method for forming exemplary portions of illustrative composite semiconductor structures or composite integrated circuits like 150 or 172. In particular, the illustrative composite semiconductor structure or integrated circuit 202 shown in FIGS. 16-20 includes a compound semiconductor portion 1022, a bipolar portion 1024, and a MOS portion 1026. In FIG. 16, a p-type doped, monocrystalline silicon substrate 210 is provided having a compound semiconductor portion 1022, a bipolar portion 1024, and an MOS portion 1026. Within bipolar portion 1024, the monocrystalline silicon substrate 210 is doped to form an N⁺ buried region 1102. A lightly p-type doped epitaxial monocrystalline silicon layer 1104 is then formed over the buried region 1102 and the substrate 210. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. As of this point, no circuitry has been formed within the compound semiconductor portion 1022.

All of the layers that have been formed during the processing of the bipolar and MOS portions of the integrated circuit are now removed from the surface of compound semiconductor portion 1022. A bare silicon surface is thus provided for the subsequent processing of this portion, for example in the manner set forth above.

An accommodating buffer layer 224 is then formed over the substrate 210 as illustrated in FIG. 17. The accommodating buffer layer will form as a monocrystalline layer over the properly prepared (i.e., having the appropriate template layer) bare silicon surface in portion 1022. The portion of layer 224 that forms over portions 1024 and 1026, however, may be polycrystalline or amorphous because it is formed over a material that is not monocrystalline, and therefore, does not nucleate monocrystalline growth. The accommodating buffer layer 224 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 222 is formed along the uppermost silicon surfaces of the integrated circuit 202. This amorphous intermediate layer 222 typically includes an oxide of silicon and has a thickness and range of approximately 1-5 nm. In one particular embodiment, the thickness is approximately 2 nm. Following the formation of the accommodating buffer layer 224 and the amorphous intermediate layer 222, a template layer 226 is then formed and has a thickness in a range of approximately one to ten monolayers of a material. In one particular embodiment, the material includes titanium-arsenic, strontium-oxygen-arsenic, or other similar materials as previously described with respect to FIGS. 1-5. Layers 222 and 224 may be subject to an annealing process as described above in connection with FIG. 3 to form a single amorphous accommodating layer.

A monocrystalline compound semiconductor layer 232 is then epitaxially grown overlying the monocrystalline portion of accommodating buffer layer 224 (or over the amorphous accommodating layer if the annealing process described above has been carried out) as shown in FIG. 18. The portion of layer 232 that is grown over portions of layer 224 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-500 nm. In this particular embodiment, each of the elements within the template layer are also present in the accommodating buffer layer 224, the monocrystalline compound semiconductor material 232, or both. Therefore, the delineation between the template layer 226 and its two immediately adjacent layers disappears during processing. Therefore, when a transmission electron microscopy (TEM) photograph is taken, an interface between the accommodating buffer layer 224 and the monocrystalline compound semiconductor layer 232 is seen.

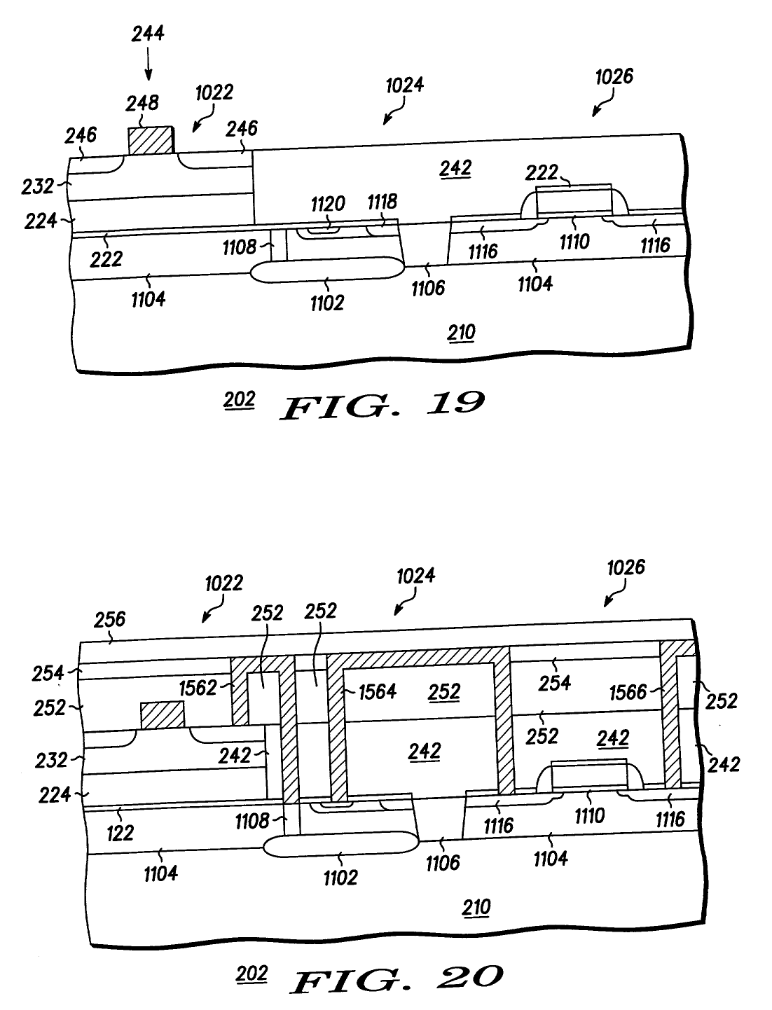

At this point in time, sections of the compound semiconductor layer 232 and the accommodating buffer layer 224 (or of the amorphous accommodating layer if the annealing process described above has been carried out) are removed from portions overlying the bipolar portion 1024 and the MOS portion 1026 as shown in FIG. 19. After the section is removed, an insulating layer 242 is then formed over the substrate 210. The insulating layer 242 can include a number of materials such as oxides, nitrides, oxynitrides, low-k dielectrics, or the like. As used herein, low-k is a material having a dielectric constant no higher than approximately 3.5. After the insulating layer 242 has been deposited, it is then polished, removing portions of the insulating layer 242 that overlie monocrystalline compound semiconductor layer 232.

A transistor 244 is then formed within the monocrystalline compound semiconductor portion 1022. A gate electrode 248 is then formed on the monocrystalline compound semiconductor layer 232. Doped regions 246 are then formed within the monocrystalline compound semiconductor layer 232. In this embodiment, the transistor 244 is a metal-semiconductor field-effect transistor (MESFET). If the MESFET is an n-type MESFET, the doped regions 246 and monocrystalline compound semiconductor layer 232 are also n-type doped. If a p-type MESFET were to be formed, then the doped regions 246 and monocrystalline compound semiconductor layer 232 would have just the opposite doping type. The heavier doped (N⁺) regions 246 allow ohmic contacts to be made to the monocrystalline compound semiconductor layer 232. At this point in time, the active devices within the integrated circuit have been formed. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 202 as illustrated in FIG. 20. An insulating layer 252 is formed over the substrate 210. The insulating layer 252 may include an etch-stop or polish-stop region that is not illustrated in FIG. 20. A second insulating layer 254 is then formed over the first insulating layer 252. Portions of layers 254, 252, 242, 224, and 222 are removed to define contact openings where the devices are to be interconnected. Interconnect trenches are formed within insulating layer 254 to provide the lateral connections between the contacts. As illustrated in FIG. 20, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown.

A passivation layer 256 is formed over the interconnects 1562, 1564, and 1566 and insulating layer 254. Other electrical connections are made to the transistors as illustrated as well as to other electrical or electronic components within the integrated circuit 202 but are not illustrated in the figures. Further, additional insulating layers and interconnects may be formed as necessary to form the proper interconnections between the various components within the integrated circuit 202.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion into the compound semiconductor portion 1022 or the MOS portion 1024. Therefore, the requirement of special fabricating steps solely used for making a bipolar transistor can be eliminated. Therefore, there would only be a compound semiconductor portion and a MOS portion to the integrated circuit.

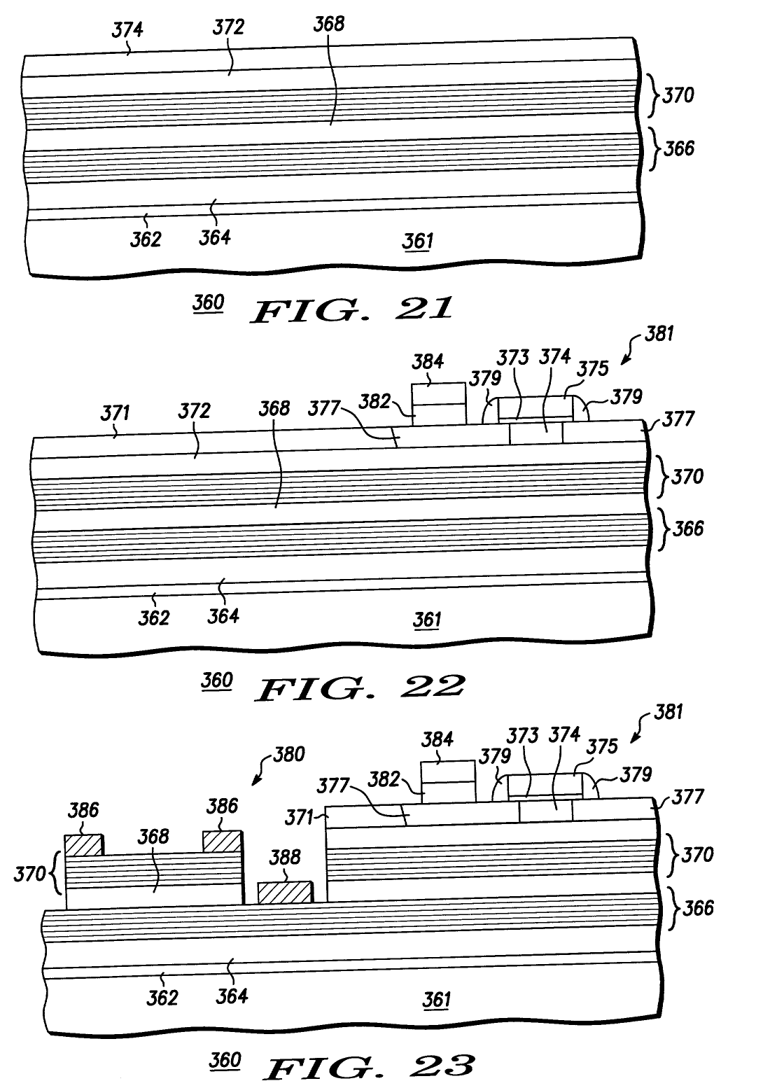

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 21-27 include illustrations of one embodiment.

FIG. 21 includes an illustration of a cross-section view of a portion of an integrated circuit 360 that includes a monocrystalline silicon wafer 361, having a doped region 363. An amorphous intermediate layer 362 and an accommodating buffer layer 364, similar to those previously described, have been formed over wafer 361. Layers 362 and 364 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 21, the lower mirror layer 366 includes alternating layers of compound semiconductor materials. For example, the first, third, and fifth films within the optical laser may include a material such as gallium arsenide, and the second, fourth, and sixth films within the lower mirror layer 366 may include aluminum gallium arsenide or vice versa. Layer 368 includes the active region that will be used for photon generation. Upper mirror layer 370 is formed in a similar manner to the lower mirror layer 366 and includes alternating films of compound semiconductor materials. In one particular embodiment, the upper mirror layer 370 may be p-type doped compound semiconductor materials, and the lower mirror layer 366 may be n-type doped compound semiconductor materials.

Another accommodating buffer layer 372, similar to the accommodating buffer layer 364, is formed over the upper mirror layer 370. In an alternative embodiment, the accommodating buffer layers 364 and 372 may include different materials. However, their function is essentially the same in that each is used for making a transition between a compound semiconductor layer and a monocrystalline Group IV semiconductor layer. Layer 372 may be subject to an annealing process as described above in connection with FIG. 3 to form an amorphous accommodating layer. A monocrystalline Group IV semiconductor layer 374 is formed over the accommodating buffer layer 372. In one particular embodiment, the monocrystalline Group IV semiconductor layer 374 includes germanium, silicon germanium, silicon germanium carbide, or the like.

In FIG. 22, the MOS portion is processed to form electrical components within this upper monocrystalline Group IV semiconductor layer 374. As illustrated in FIG. 22, a field isolation region 371 is formed from a portion of layer 374. A gatedielectric layer 373 is formed over the layer 374, and a gate electrode 375 is formed over the gate dielectric layer 373. Doped regions 377 are source, drain, or source/drain regions for the transistor 381, as shown. Sidewall spacers 379 are formed adjacent to the vertical sides of the gate electrode 375. Other components can be made within at least a part of layer 374. These other components include other transistors (n-channel or p-channel), capacitors, transistors, diodes, and the like.

A monocrystalline Group IV semiconductor layer is epitaxially grown over one of the doped regions 377. An upper portion 384 is P+ doped, and a lower portion 382 remains substantially intrinsic (undoped) as illustrated in FIG. 22. The layer can be formed using a selective epitaxial process. In one embodiment, an insulating layer (not shown) is formed over the transistor 381 and the field isolation region 371. The insulating layer is patterned to define an opening that exposes one of the doped regions 377. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 384 is formed, the insulating layer is then removed to form the resulting structure shown in FIG. 22.

The next set of steps is performed to define the optical laser 380 as illustrated in FIG. 23. The field isolation region 371 and the accommodating buffer layer 372 are removed over the compound semiconductor portion of the integrated circuit. Additional steps are performed to define the upper mirror layer 370 and active layer 368 of the optical laser 380. The sides of the upper mirror layer 370 and active layer 368 are substantially coterminous.

Contacts 386 and 388 are formed for making electrical contact to the upper mirror layer 370 and the lower mirror layer 366, respectively, as shown in FIG. 23. Contact 386 has an annular shape to allow light (photons) to pass out of the upper mirror layer 370 into a subsequently formed optical waveguide.

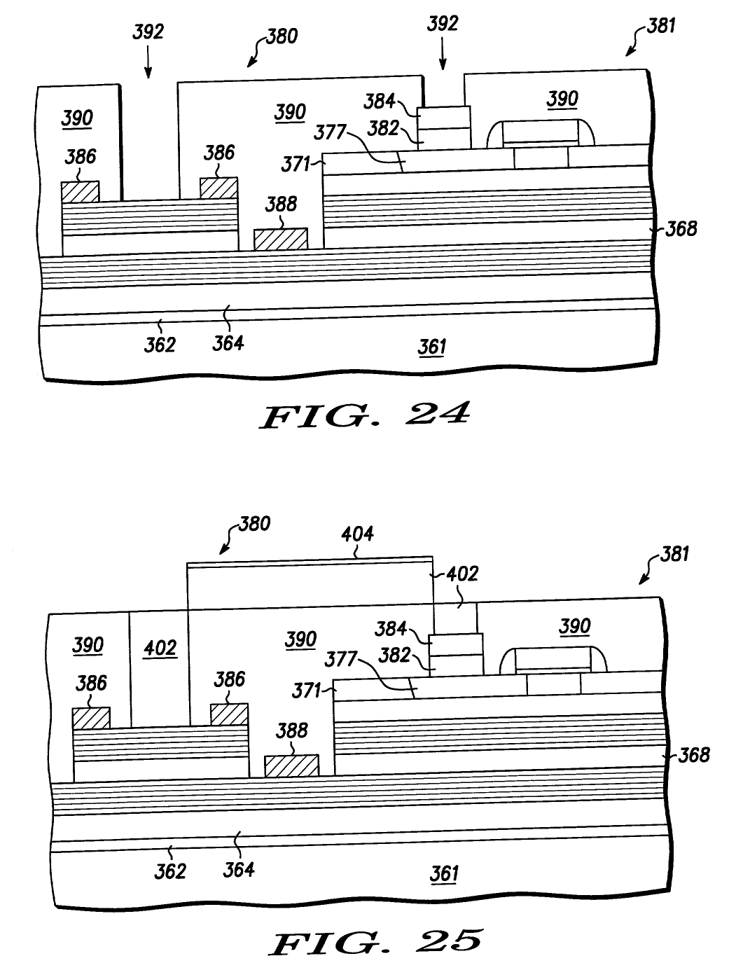

An insulating layer 390 is then formed and patterned to define optical openings extending to the contact layer 386 and one of the doped regions 377 as shown in FIG. 24. The insulating material can be any number of different materials, including an oxide, nitride, oxynitride, low-k dielectric, or any combination thereof. After defining the openings 392, a higher refractive index material 402 is then formed within the openings to fill them and to deposit the layer over the insulating layer 390 as illustrated in FIG. 25. With respect to the higher refractive index material 402, “higher” is in relation to the material of the insulating layer 390 (i.e., material 402 has a higher refractive index compared to the insulating layer 390). Optionally, a relatively thin lower refractive index film (not shown) could be formed before forming the higher refractive index material 402. A hard mask layer 404 is then formed over the high refractive index layer 402. Portions of the hard mask layer 404, and high refractive index layer 402 are removed from portions overlying the opening and to areas closer to the sides of FIG. 25.

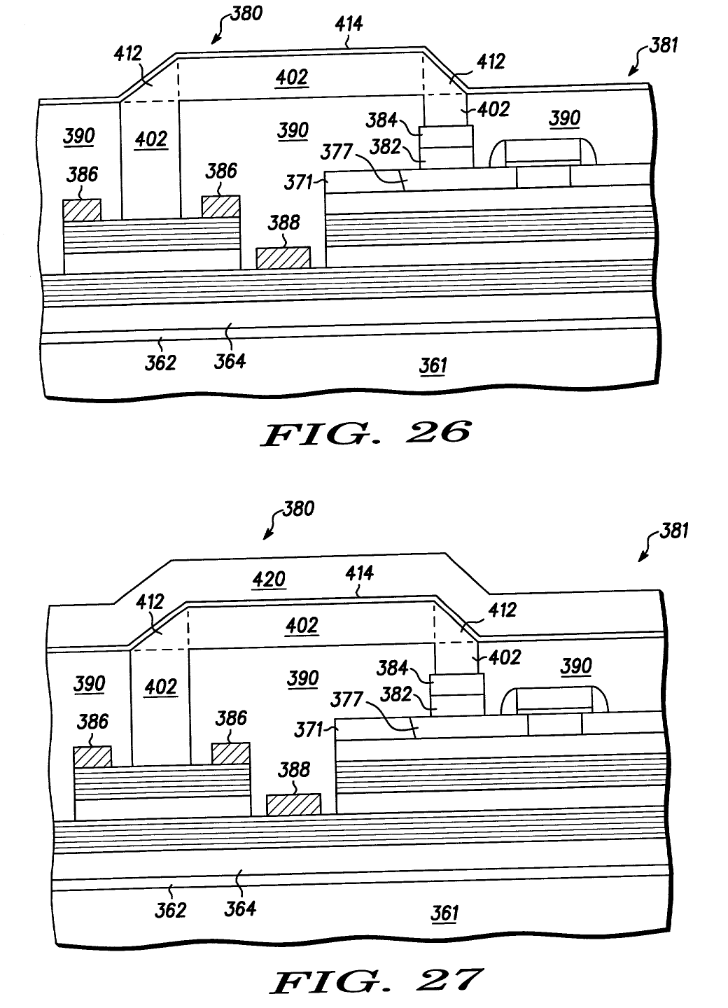

The balance of the formation of the optical waveguide, which is an optical interconnect, is completed as illustrated in FIG. 26. A deposition procedure (possibly a dep-etch process) is performed to effectively create sidewall sections 412. In this embodiment, the sidewall sections 412 are made of the same material as material 402. The hard mask layer 404 is then removed, and a low refractive index layer 414 (low relative to material 402 and layer 412) is formed over the higher refractive index material 412 and 402 and exposed portions of the insulating layer 390. The dash lines in FIG. 26 illustrate the border between the high refractive index materials 402 and 412. This designation is used to identify that both are made of the same material but are formed at different times.

Processing is continued to form a substantially completed integrated circuit as illustrated in FIG. 27. A passivation layer 420 is then formed over the optical laser 380 and MOSFET transistor 381. Although not shown, other electrical or optical connections are made to the components within the integrated circuit but are not illustrated in FIG. 27. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 361, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such the all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor structure comprising:
a monocrystalline silicon substrate;
an amorphous oxide material overlying the monocrystalline silicon substrate;
a perovskite oxide material overlying the amorphous oxide material;
a monocrystalline compound semiconductor material overlying the monocrystalline perovskite oxide material; and
a strained-layer superlattice portion formed overlying the monocrystalline compound semiconductor material.

2. The semiconductor structure of claim 1, wherein the monocrystalline silicon substrate comprises a (100) silicon material having a surface.

3. The semiconductor structure of claim 1, wherein the monocrystalline compound semiconductor material comprises a layer of GaAs.

4. The semiconductor structure of claim 1, wherein a thickness of the monocrystalline compound semiconductor material is greater than 0.2 μm and less than 0.5 μm.

5. The semiconductor structure of claim 1, wherein the strained-layer superlattice portion comprises a layer of InGaAs.

6. The semiconductor structure of claim 5, wherein the thickness of InGaAs layer is greater than 0.1 μm and less than 0.3 μm.

7. The semiconductor structure of claim 1, wherein the strained-layer superlattice portion comprises alternating layers of InGaAs and GaAs.

8. The semiconductor structure of claim 7, wherein the strained-layer superlattice portion comprises 5-10 periods of alternating layers of InGaAs and GaAs.

9. The semiconductor structure of claim 7, wherein a thickness of each of the alternating layers of InGaAs and GaAs is about 1 nm to about 3 nm.

10. The semiconductor structure of claim 1, wherein the strained-layer superlattice portion comprises alternating layers of GaAsP and GaAs.

11. The semiconductor structure of claim 10, wherein the strained-layer superlattice portion comprises 5-10 periods of alternating layers of GaAsP and GaAs.

12. The semiconductor structure of claim 10, wherein a thickness of each of the alternating layers of GaAsP and GaAs is about 1 nm to about 3 nm.

13. The semiconductor structure of claim 1, further comprising an additional layer of monocrystalline material formed overlying the strained-layer superlattice portion.

14. The semiconductor structure of claim 13, wherein a thickness of the additional layer of monocrystalline material is about 0.5 μm to about 2 μm.

15. The semiconductor structure of claim 1, further comprising an additional strained-layer superlattice portion formed overlying the additional layer of monocrystalline material.

16. The semiconductor structure of claim 1, further comprising a plurality of layers of monocrystalline material formed above the strained-layer superlattice portion.

17. The semiconductor structure of claim 1, further comprising a plurality of strained-layer superlattice portions formed above the monocrystalline compound semiconductor material.

18. The semiconductor structure of claim 1, wherein the perovskite oxide material is amorphous.

19. The semiconductor structure of claim 1, wherein the perovskite oxide material is monocrystalline.

20. The semiconductor structure of claim 1, further comprising a template layer between the perovskite oxide material and the monocrystalline compound semiconductor material.

21. The semiconductor structure of claim 20, wherein the template layer comprises material selected from the group consisting of Sr, Sr—O, Ti, and Ti—O.

22. The semiconductor structure of claim 1, wherein the perovskite oxide material comprises an oxide selected from the group consisting of alkaline earth metal titanates, alkaline earth metal zirconates, alkaline earth metal hafnates, alkaline earth metal tantalates, alkaline earth metal ruthenates, and alkaline earth metal niobates.

23. The semiconductor structure of claim 1, wherein the perovskite oxide material comprises SrₓBa₁₋ₓTiO₃ where x ranges from 0 to 1.

24. The semiconductor structure of claim 1, wherein the monocrystalline compound semiconductor material comprises a material selected from the group consisting of: III-V compounds, mixed III-V compounds, II-VI compounds, mixed II-VI compounds, IV-VI compounds, and mixed IV-VI compounds.

25. The semiconductor structure of claim 1 wherein the monocrystalline compound semiconductor material comprises a material selected from the group consisting of: GaAs, AlGaAs, InP, InGaAs, InGaP, ZnSe, ZnSSe, PbTe, PbS, PbSe, and PbSSe.

26. The semiconductor structure of claim 1, further comprising a first active device formed at least partially in the monocrystalline compound semiconductor material.

27. The semiconductor structure of claim 26, wherein the first active semiconductor device comprises an optical device.

28. The semiconductor structure of claim 26, further comprising a second active semiconductor device formed at least partially in the monocrystalline monocrystalline silicon substrate.

29. The semiconductor structure of claim 28, further comprising an electrical connection coupling the first active semiconductor device and the second active semiconductor device.

30. The semiconductor structure of claim 1, wherein the monocrystalline silicon substrate comprises (100) silicon material having a surface that is about 2 to about 6 degrees off axis towards (011).

31. The semiconductor structure of claim 1, wherein the strained-layer superlattice portion comprises a layer of GaAsP.

32. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film; and
epitaxially forming a strained-layer superlattice material overlying the monocrystalline compound semiconductor layer.

33. The process of claim 32, further comprising the step of exposing the monocrystalline perovskite oxide film to an anneal process to convert the monocrystalline perovskite oxide film to an amorphous film.

34. The process of claim 32, wherein the step of epitaxially forming a monocrystalline compound semiconductor layer comprises growing a layer comprising GaAs.

35. The process of claim 34, wherein the step of growing a layer comprising GaAs comprises growing an initial portion of the layer at a temperature of about 300° C. to about 500° C.

36. The process of claim 35, further comprising a step of annealing the initial portion at a temperature of about 550° C. to about 800° C.

37. The process of claim 35, further comprising the step of growing a second portion of the layer at a temperature of about 300° C. to about 700° C.

38. The process of claim 32, further comprising the step of forming a template between the monocrystalline perovskite oxide film and the monocrystalline compound semiconductor layer.

39. The process of claim 38, wherein the step for forming a template comprises depositing a material selected from the group consisting of Sr, Sr—O, Ti, and Ti—O.

40. The process of claim 32, wherein the step of providing a monocrystalline silicon substrate comprises providing a (100) silicon substrate, having a surface that is off axis by about 2 degrees to about 6 degrees towards (011).

41. The process of claim 32, wherein the step of providing a monocrystalline silicon substrate comprises providing a (100) silicon substrate.

42. The process of claim 32, wherein the step of depositing a monocrystalline perovskite oxide film comprises depositing a material selected from the group consisting of barium titanate, strontium titanate, and barium strontium titanate.

43. The process of claim 32, wherein the step of epitaxially forming a strained-layer superlattice material comprises forming alternating layers of GaAs and a material selected from the group consisting of InGaAs and GaAsP.

44. The process of claim 43, wherein the step of forming alternating layers comprises forming 5-10 periods of alternating GaAs and a material selected from the group consisting of InGaAs and GaAsP.

45 The process of claim 32, wherein the step of epitaxially forming a monocrystalline compound semiconductor layer comprises growing the layer using a layer-by-layer deposition technique.

46. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate; and
epitaxially forming a monocrystalline compound semiconductor layer overlying the monocrystalline perovskite oxide film,
wherein the step of epitaxially forming comprises depositing a first portion of the monocrystalline compound semiconductor layer, exposing the first portion to an anneal process, and subsequent to the anneal process, growing a second portion of the monocrystalline compound semiconductor layer.

47. The process of claim 46, wherein the step of epitaxially forming a monocrystalline compound semiconductor layer comprises growing a layer of material comprising GaAs.

48. The process of claim 47, wherein the step of depositing a first portion of the monocrystalline compound semiconductor layer comprises depositing GaAs at a growth rate of about 0.1 μm/hour to about 0.3 μm/hour.

49. The process of claim 47, wherein the step of depositing a first portion of the monocrystalline compound semiconductor layer comprises depositing GaAs at a temperature of about 300° C. to about 500° C.

50. The process of claim 47, wherein the step of growing a second portion of the monocrystalline compound semiconductor layer comprises depositing GaAs at a growth rate of about 0.4 μm/hour to about 1.0 μm/hour.

51. The process of claim 47, wherein the step of growing a second portion of the monocrystalline compound semiconductor layer comprises depositing GaAs at a temperature of about 300° C. to about 700° C.

52. The process of claim 46, wherein the step of exposing comprises subjecting the first portion to an anneal temperature of about 550° C. to about 800° C.

53. The process of claim 46, further comprising the step of forming a strained-layer superlattice structure overlying the monocrystalline compound semiconductor layer.

54. The process of claim 53, wherein the step of forming a strained-layer superlattice structure comprises forming alternating layers of GaAs and a material selected from the group consisting of InGaAs and GaAsP.

55. The process of claim 54, wherein the step of forming alternating layers comprises forming about 5-10 periods of alternating GaAs and a material selected from the group consisting of InGaAs and GaAsP.

56. The process of claim 46, wherein the step of providing a monocrystalline silicon substrate comprises providing a (100) silicon substrate.

57. The process of claim 46, wherein the step of providing a monocrystalline silicon substrate comprises providing a (100) silicon substrate, having a surface that is off axis by about 2 degrees to about 6 degrees towards (011).

58. The process of claim 46, further comprising the step of forming a template between the monocrystalline perovskite oxide film and the monocrystalline compound semiconductor layer.

59. The process of claim 58, wherein the step for forming a template comprises depositing a material selected from the group consisting of Sr, Sr—O, Ti, and Ti—O.

60. The process of claim 46, further comprising the step of exposing the monocrystalline perovskite oxide film to an anneal process to convert the monocrystalline perovskite oxide film to an amorphous film.

61. The process of claim 46, further comprising the step of forming an electronic device using the monocrystalline silicon substrate.

62. The process of claim 46, further comprising the step of forming an electronic device using the monocrystalline compound semiconductor layer.

63. The process of claim 46, wherein the step of depositing a first portion comprises using atomic layer deposition to form a layer of GaAs.

64. The process of claim 46, wherein the step of depositing a first portion comprises growing a layer of GaAs using a layer-by-layer deposition technique.

65. A semiconductor structure comprising:
a monocrystalline silicon substrate;
an amorphous silicon oxide material overlying the monocrystalline silicon substrate;
a strontium titanate material overlying the amorphous silicon oxide material;
a monocrystalline GaAs material overlying the strontium titanate material; and
a strained-layer superlattice portion formed overlying the monocrystalline GaAs material, wherein the strained-layer superlattice portion comprises a material selected from the group consisting of InGaAs and GaAsP.
